(19) United States
(12) Patent Application Publication
(10) Pub. No.: US 2014/0007921 A1
(43) Pub. Date: Jan. 9, 2014

(54) WAVELENGTH CONVERSION ELEMENT AND PHOTOELECTRIC CONVERSION DEVICE

(71) Applicant: FUJIFILM Corporation, Tokyo (JP)

(72) Inventor: Teruhiko KURAMACHI, Ashigara-kami-gun (JP)

(73) Assignee: FUJIFILM Corporation, Tokyo (JP)

(21) Appl. No.: 14/024,397

(22) Filed: Sep. 11, 2013

Related U.S. Application Data
(63) Continuation of application No. PCT/JP2011/079346, filed on Dec. 19, 2011.

(30) Foreign Application Priority Data
Mar. 25, 2011 (JP) 2011-067818

(51) Int. Cl. H01L 31/055; G02F 1/35

(52) U.S. Cl. CPC H01L 31/055; G02F 1/353
USPC 136/247; 359/326

(57) ABSTRACT

A wavelength conversion element includes at least one wavelength conversion layer. The wavelength conversion layer has a matrix layer and particles that is disposed in the matrix layer. The matrix layer is formed of a curable resin material or an inorganic material with a bandgap of 3 eV or more. The particles are formed of a wavelength conversion composition for wavelength-converting absorbed light in a specific wavelength range into light having energy lower than energy of the absorbed light, and that have a particle diameter of 3 nm to 20 nm. An interval between neighboring particles is equal to or less than the particle diameter of the particles. Consequently, the wavelength conversion layer prevents reflection of light in a wavelength range other than the specific wavelength range.

### BACKGROUND OF THE INVENTION

The present invention relates to a wavelength conversion element having semiconductor quantum dots and a photoelectric conversion device including the wavelength conversion element, and more particularly, to a wavelength conversion element which converts short-wavelength light with a wavelength of 500 nm or less having poor energy utilization efficiency into light of a wavelength easily absorbed by a photoelectric conversion layer and which converts one photon into two or more photons having half energy or less and a photoelectric conversion device which efficiently converts solar energy into electric energy.

At the present time, studies of solar cells have been actively made. Of the solar cells, in a PN-junction solar cell in which a P-type semiconductor and an N-type semiconductor are joined and a PIN-junction solar cell in which a P-type semiconductor, an I-type semiconductor, and an N-type semiconductor are joined, electrons are excited from a valence band to a conduction band by absorbing sunlight having energy equal to or more than a bandgap (Eg) between the conduction band and the valence band of the constituent semiconductors, holes are created in the valence band, and thus an electromotive force is generated in the solar cell. The PN-junction solar cell and the PIN-junction solar cell have a single band gap and are called single-junction solar cells.

A single-junction Si solar cell such as a crystalline Si solar cell has been proposed in which sunlight is wavelength-converted into light with a wavelength distribution suitable for a spectral sensitivity characteristic of a single-junction Si solar cell to improve photovoltaic power generation efficiency by adding rare-earth particulates and rare-earth complexes, for example, Yb³⁺-Ln³⁺(Ln³⁺=Tb³⁺, Ce³⁺) co-doped glass, to a tempered glass or a resin such as EVA (for example, see JP 2010-219551 A and “Enhancing the performance of silicon solar cells via the application of passive luminescence conversion layers” by B. S. Richards, Solar Energy Materials and Solar Cell 90 (2006) 2329-2337 (hereinafter called “Literature 1”).

Since crystalline Si has Eg (bandgap) 1.2 eV, absorbed short-wavelength light with a wavelength of 1000 nm or more has excess energy of equal to or more than Eg (bandgap) and is consumed in lattice vibration. Accordingly, sunlight cannot be efficiently converted in energy. Therefore, a study of light-light conversion of converting light of a wavelength of 500 nm or less in sunlight into light of a wavelength of about 1000 nm and converting one photon into two or more photons having half energy or less has been carried out (for example, JP 2010-118491 A and “Modifying the solar spectrum to enhance silicon solar cell efficiency - An overview of available materials” by C. Strumpel, Solar Energy Materials and Solar Cell 91 (2007) 238-249 (hereinafter called “Literature 2”).

JP 2010-219551 A describes a wavelength conversion layer formed by curing a wavelength conversion composition comprising a curable resin and oxide particulates containing a wavelength conversion material which converts a wavelength of absorbed light. The wavelength conversion material is composed of semiconductor particulates such as Si or ZnO with a particle diameter of 1 to 10 nm. In JP 2010-219551 A, the wavelength conversion layer is formed on a photovoltaic device. It is also described that the wavelength conversion layer is provided to have an uneven structure with a height difference of 100 μm to 3000 μm in a plane of the photovoltaic device and that the uneven structure has a fine uneven shape. It is described that the height difference of the fine uneven shape preferably ranges from 100 nm to 500 nm, from the viewpoint of optical confinement.

JP 2010-118491 A describes a photoelectric conversion device comprising a photoelectric conversion unit and a wavelength conversion unit (wavelength conversion element). The wavelength conversion unit is disposed on the light incidence side of the photoelectric conversion unit and the wavelength conversion unit comprises quantum dots d and a layer surrounding the quantum dots. The layer surrounding the quantum dots is a matrix layer.

JP 2010-118491 A describes that the quantum dots d may be regularly arranged horizontally and vertically or the quantum dots d may be two-dimensionally arranged randomly between thin films.

Literature 1 theoretically proposes that when a passive light-emitting device converting high energy into low energy or a passive light-emitting device converting low energy into high energy is added to a single-junction solar cell such as a crystalline Si solar cell, power generation efficiency is improved from 25% to 36% depending on irradiation conditions of pseudo sunlight.

Conversion of high energy into lower energy is called down-conversion and conversion of low energy into high energy is called up-conversion.

In Literature 1, an experiment is carried out using a sheet in which NaY_{0.8}F₄:Er_{0.2}³⁺ particles with a diameter of 5 μm are introduced into a polymer.

Here, since a light-emitting material having rare-earth particulates and rare-earth complexes added thereto has a low light absorption coefficient, there is a problem in that a structure easily absorbing light such as a thick film shape or a fiber shape should be realized to enhance light absorption efficiency for applications thereof. Accordingly, in the field of light source for optical communication, a study of causing Si quantum dots to absorb light and causing rare-earth particulates to emit light by adding rare-earth Er to the Si quantum dots so as to improve the features of the rare-earth particles having a low light absorption coefficient has been carried out (for example, see Literature 2).

Literature 2 proposes to use a quantum-cutting effect (multiple exciton generation (MEG) effect) of converting one photon into two or more photons having half energy or less in order to improve the external quantum efficiency of the rare-earth particulates such as NaYF:Er. Literature 2 also introduces that in an experiment using PbSe_{QD} by Nozik et al., the external quantum efficiency was set to 218%.

Based on the above, a proposal is being made in which photovoltaic power generation efficiency of a C—Si (crystalline silicon) solar cell is improved by adding ytterbium or the like to Si quantum dots to absorb light with a wavelength of 500 nm or less and to convert a photon having optical energy of 2.4 eV or more into two or more photons having optical energy of 1.2 eV or less.

### SUMMARY OF THE INVENTION

However, as described above, the down-conversion light-light conversion film has a function of wavelength-converting light in a wavelength range with energy of two or more times Eg of the photoelectric conversion layer but does not exhibit a wavelength conversion effect for a wavelength range with energy of two or less times Eg of the photoelectric conversion layer.

From this point of view, there is a need for a wavelength conversion film capable of wavelength-converting light in a specific wavelength range of which the wavelength has not been converted. Thus, it is desired to improve the wavelength conversion efficiency of a solar cell and to improve the total power generation efficiency thereof by means of such a wavelength conversion film.

In JP 2010-219551 A, when the wavelength conversion layer is formed in an uneven shape on a photovoltaic layer or in the photovoltaic layer, cost is incurred in forming the wavelength conversion layer in an uneven shape. In addition, it is difficult to uniformly form the uneven shape on the photovoltaic layer or in the photovoltaic layer and hence, difficult to achieve an effect of improvement in reflection loss due to the unevenness. JP 2010-118491 A does not consider incident light at all.

In literature 1, a population inversion state should be formed to efficiently emit light. Accordingly, it is necessary to arrange particulates in an array suitable for the population inversion state, but in a sheet formed by mixing particulates into a polymer, particulates are often randomly arranged as long as any particular measures are not performed thereon. Since rare-earth particulates such as NaYF:Er have a small absorption cross-section and have a particle diameter of 5 μm which does not exert a quantum effect, the external quantum efficiency thereof is relatively low and it is thus necessary to form a film of which the thickness is relatively large.

In Literature 2, there is no effect for the wavelength range with energy of two times or less Eg of the photoelectric conversion layer with only the improvement based on the MEG effect. Accordingly, the improvement described in Literature 2 contributes to only some wavelengths of sunlight and the effect of the improvement is small as an effect for enhancing the total power generation efficiency of a solar cell.

The present invention is made to solve the above-mentioned problems of the conventional technologies and an object thereof is to provide a wavelength conversion element in which a wavelength conversion region is improved and reflection loss of incident light is reduced and a photoelectric conversion device including the wavelength conversion element.

In order to achieve the foregoing object, the present invention provides as the first aspect a wavelength conversion element comprising: at least one wavelength conversion layer comprising a matrix layer that is formed of a curable resin material or an inorganic material with a bandgap of 3 eV or more and particles that are disposed in the matrix layer, that are formed of a wavelength conversion composition for wavelength-converting absorbed light in a specific wavelength range into light having energy lower than energy of the absorbed light, and that have a particle diameter of 3 nm to 20 nm, wherein the particles are arranged so that an interval between neighboring particles is equal to or less than the particle diameter of the particles, and wherein the wavelength conversion layer prevents reflection of light in a wavelength range other than the specific wavelength range.

Preferably, a plurality of the wavelength conversion layers are stacked, and the particles of each matrix layer in a stacked direction are arranged so that an interval between neighboring particles in the stacked direction is equal to or less than the particle diameter of the particles.

Preferably, the interval between neighboring particles is equal to or less than 10 nm, a deviation σ_{d} of the particle diameter is 1<σ_{d}<10 nm, and the particle diameter of the particles varies in the range of the deviation.

The particles are formed of Si, Ge, SiGe mixed crystal, InN, or InGaN mixed crystal, for example.

The inorganic material is SiOx (0<x<2), SiNx(0<x<¾), or InGaN mixed crystal, for example.

The present invention provides as the second aspect a photoelectric conversion device comprising: a photoelectric conversion layer; and the wavelength conversion element being disposed on an incident light side of the photoelectric conversion layer, wherein the wavelength conversion element wavelength-converts light in a specific wavelength range with energy of two or more times a bandgap of the photoelectric conversion layer into light with energy of the bandgap of the photoelectric conversion layer and prevents reflection of light in a wavelength range other than the specific wavelength range.

Preferably, an effective refractive index of the wavelength conversion element is an intermediate refractive index between a reflective index of the photoelectric conversion layer and a refractive index of air. In this case, an effective refractive index n of the wavelength conversion element at a wavelength of 533 nm is 1.7<n<3.0, for example.

Preferably, a bandgap of the particles disposed in the matrix layer of the wavelength conversion element is larger than the bandgap of the photoelectric conversion layer.

According to the present invention, it is possible to wavelength-convert absorbed light in a specific wavelength range into light having energy lower than that of the absorbed light and to prevent reflection of light in a wavelength range other than the specific wavelength range. Accordingly, for example, by disposing the wavelength conversion element on the light incidence side of the photoelectric conversion layer of a photoelectric conversion device, it is possible to improve power generation efficiency of the photoelectric conversion device.

When polycrystalline silicon is used in the photoelectric conversion layer, various plane orientations appear and thus reflectance is not uniform. Accordingly, even if an antireflection film effective for a certain plane orientation is formed, it is not effective for the entire photoelectric conversion layer. However, the wavelength conversion element of the invention can prevent reflection of light in a wavelength range other than the specific wavelength range, thereby suppressing reflection loss to a low level. Accordingly, even when polycrystalline silicon is used in the photoelectric conversion layer, it is possible to further improve power generation efficiency.

In addition, when the wavelength conversion element is provided, the wavelength conversion element has only to be disposed and does not require etching or the like. Accordingly, no damage due to etching or the like occurs in the photoelectric conversion device. As a result, it is possible to suppress occurrence of manufacturing failure.

### BRIEF DESCRIPTION OF THE DRAWINGS

FIG. 1 is a schematic cross-sectional view illustrating a wavelength conversion element according to an embodiment of the present invention.

FIG. 2 is a schematic diagram illustrating a multiple exciton generation effect.

FIG. 3 is a schematic diagram illustrating a sunlight spectrum and a spectral sensitivity curve of a crystalline Si.

FIG. 4 is a graph illustrating a difference in reflectance due to a difference in configuration of an antireflection film.

FIG. 5A is a graph illustrating a relationship between a content of Si quantum dots in a SiO₂ matrix layer and a refractive index and

FIG. 5B is a graph illustrating a relationship between an interval of Si quantum dots in a SiO₂ matrix layer and a refractive index.

FIG. 6 is a graph illustrating reflectance of SiO₂ film/wavelength conversion element (Si_{QD}/SiO₂ₘₐₜ)/Si substrate, where the wavelength conversion element has a refractive index of 1.80.

FIG. 7 is a graph illustrating reflectance of SiO₂ film/wavelength conversion element (Si_{QD}/SiO₂ₘₐₜ)/Si substrate, where the wavelength conversion element has a refractive index of 2.35.

FIG. 8 is a graph illustrating a relationship between a difference in effective refractive index and emission intensity in the wavelength conversion element.

FIG. 9A is a graph illustrating a relationship between uniformity of quantum dots and emission intensity in the wavelength conversion element,

FIG. 9B is a diagram illustrating a TEM image of the wavelength conversion element in which quantum dots are not uniform, and

FIG. 9C is a diagram illustrating a TEM image of the wavelength conversion element in which quantum dots are uniform.

FIG. 10 is a schematic cross-sectional view illustrating a photoelectric conversion device including a wavelength conversion element according to an embodiment of the present invention.

FIG. 11 is a graph illustrating a relationship between a difference in effective refractive index and external quantum efficiency of the wavelength conversion element included in the photoelectric conversion device.

### DETAILED DESCRIPTION OF THE INVENTION

Hereinafter, a wavelength conversion element and a photoelectric conversion device according to the present invention will be described in detail based on exemplary embodiment shown in the accompanying drawings.

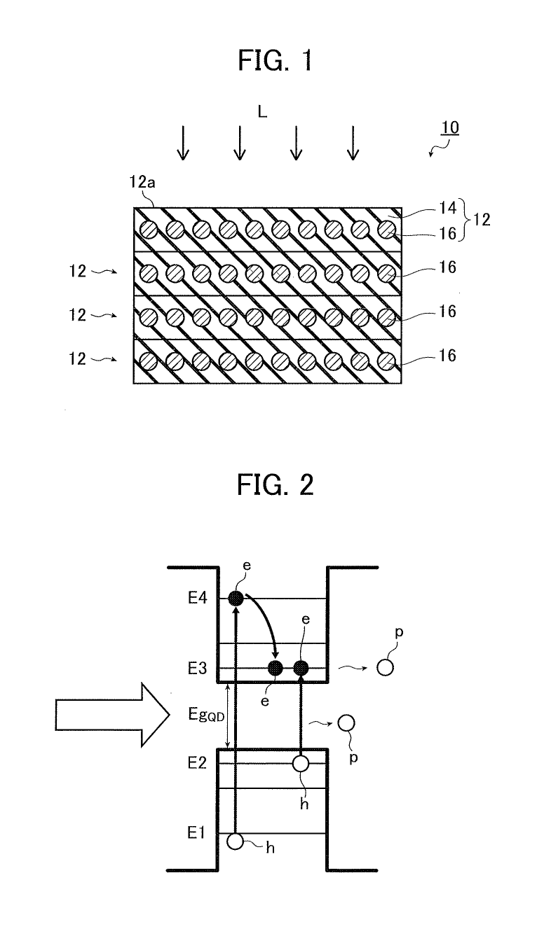

FIG. 1 is a schematic cross-sectional view illustrating a wavelength conversion element according to an embodiment of the present invention.

A wavelength conversion element 10 shown in FIG. 1 has, for example, a multi-layered structure in which plural wavelength conversion films 12 are stacked. Each wavelength conversion film 12 comprises a matrix layer 14 and plural quantum dots 16 contained in the matrix layer 14. In the wavelength conversion film 12, for example, the quantum dots 16 are arranged in a line. The wavelength conversion film 12 is not limited to the configuration in which the quantum dots 16 are arranged in a line in the matrix layer 14.

The wavelength conversion element 10 has at least one wavelength conversion film 12, and when only one wavelength conversion film 12 is disposed, it is also called a wavelength conversion element 10.

The wavelength conversion element 10 and the wavelength conversion film 12 have a function of absorbing incident light L and wavelength-converting the absorbed light in a specific wavelength range into light in a wavelength range having energy lower than that of the absorbed light (hereinafter, this function is referred to as a wavelength conversion function) and a function of confining the incident light L (hereinafter, this function is referred to as an optical confinement function).

In the wavelength conversion element 10 and the wavelength conversion film 12, the wavelength conversion function is specifically a down-conversion function. The down-conversion function is exhibited by an effect of generating one or more photons per each absorbed photon, which is called a multiple exciton generation effect. For example, as shown in FIG. 2, in the case where a quantum well is formed by a quantum dot 16 and a photon having energy equal to or more than EG_{QD} (bandgap of the quantum dot) enters the quantum dot 16, an electron located at a low energy level (E1) is excited to a higher energy level (E4), and when the electron subsequently drops to a lower energy level (E3), a photon having energy lower than that of the incident photon is discharged. Also, when an electron located at a lower energy level (E2) is excited to a higher energy level (E3), a photon having energy lower than that of the incident photon is discharged. In this way, two electrons having energy lower than that of a photon are discharged for each photon, whereby the wavelength conversion is carried out.

Regarding the wavelength conversion function of the wavelength conversion element 10, a wavelength range to be converted and a wavelength after conversion are appropriately selected depending on the application of the wavelength conversion element 10.

When the wavelength conversion element 10 is disposed, for example, on a photoelectric conversion layer of a silicon solar cell of which Eg (bandgap) is 1.2 eV, it is assumed that the wavelength conversion element 10 has a function of wavelength-converting light in a wavelength range having energy of two or more times 1.2 eV, that is, energy equal to or more than 2.4 eV, into light of a wavelength having energy corresponding to the bandgap.

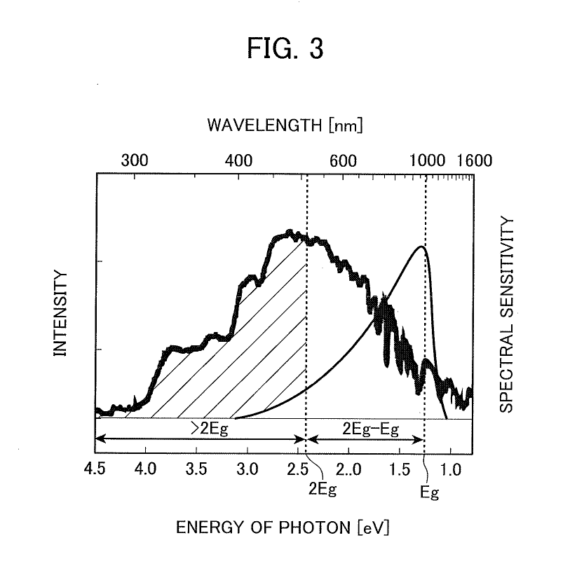

As shown in FIG. 3, comparing a sunlight spectrum and a spectral sensitivity curve of crystalline Si, the intensity of the sunlight spectrum in the wavelength range of the bandgap of crystalline Si is low. Accordingly, by wavelength-converting, of sunlight, light in a wavelength range having energy two or more times the bandgap of crystalline Si, that is, energy equal to or more than 2.4 eV, into photons having low energy, for example, light of 1.2 eV, that is, light of a wavelength of about 1100 nm, light effective for photoelectric conversion can be supplied to the photoelectric conversion layer formed of crystalline Si. Accordingly, it is possible to enhance conversion efficiency of a solar cell.

In the wavelength conversion element 10, the optical confinement function is an antireflection function.

When the photoelectric conversion layer on which the wavelength conversion element 10 (wavelength conversion film 12) is disposed is formed of crystalline Si, the refractive index n_{PV} thereof is 3.6. The refractive index nₐᵢᵣ of air in the space in which the wavelength conversion element 10 and the photoelectric conversion layer are disposed is 1.0.

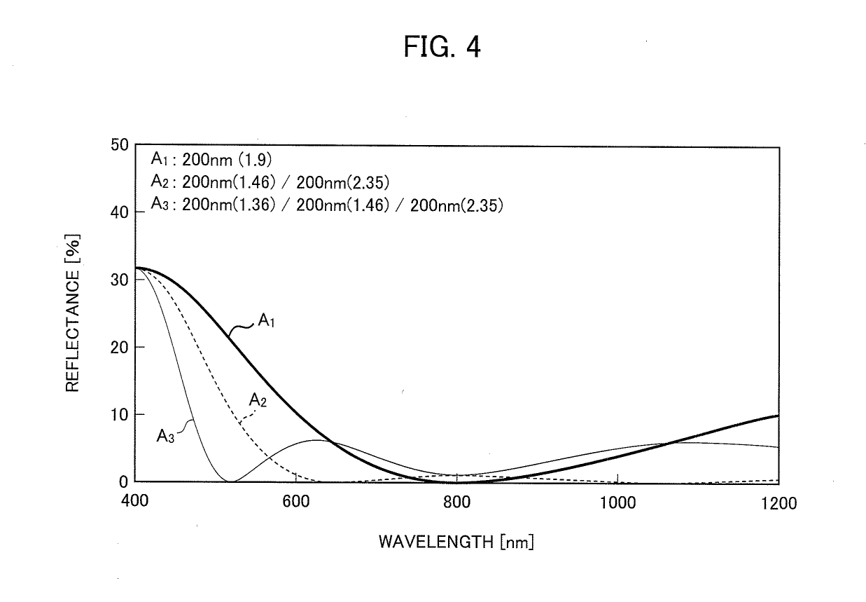

Here, in the case where the wavelength conversion element 10 is considered as an antireflection film, as shown in FIG. 4 for example, when comparing a single-layered film (reference sign A₁) with a refractive index of 1.9, a two-layered film (reference sign A₂) with a refractive index of 1.46/2.35, and a three-layered film (reference sign A₃) with a refractive index of 1.36/1.46/2.35 with each other, the wavelength conversion element 10 having a layer of which the refractive index is 2.35 can reduce the reflectance.

Thus, in order to cause the wavelength conversion element 10 (wavelength conversion film 12) to exhibit the antireflection function, the function can be achieved with the effective refractive index n of the wavelength conversion element 10 (wavelength conversion film 12) being an intermediate refractive index between the refractive index n_{PV} of the photoelectric conversion layer and the refractive index of air. The refractive index n_{PV} is 3.6 when using crystalline silicon.

In this embodiment, in consideration of the application of the wavelength conversion element 10 (wavelength conversion film 12) and the like, the effective refractive index n of the wavelength conversion element 10 (wavelength conversion film 12) is, for example, 1.7<n<3.0 at a wavelength of 533 nm. The effective refractive index n is preferably 1.7<n<2.5 at a wavelength of 533 nm.

In order to allow the wavelength conversion element 10 to perform the above-mentioned wavelength conversion function and the above-mentioned optical confinement function, the wavelength conversion film 12 has the following configuration.

In the wavelength conversion film 12, the matrix layer 14 is composed of a transparent curable resin material or a transparent inorganic material with a bandgap of 3 eV or more.

For example, a photo-curable resin or a thermosetting resin is used as the curable resin material of the matrix layer 14, and the curable resin material is not particularly limited as long as it can transmit light. Examples of the photo-curable resin and the thermosetting resin include an acryl resin, an epoxy resin, a silicone resin, and an ethylene vinyl acetate (EVA) resin.

Examples of the silicone resin include commercially-available silicone resins for LED. As the ethylene vinyl acetate (EVA) resin, for example, Solar EVA (trademark) made by Mitsui Chemicals Fabro Inc. (which is currently Riken Fabro Corporation) and the like can be used. An ionomer resin or the like may also be used as the matrix layer 14.

Examples of the epoxy resin include a bisphenol A epoxy resin, a bisphenol F epoxy resin, a bisphenol S epoxy resin, a naphthalene epoxy resin, hydrates of these epoxy resins, an epoxy resin having a dicyclopentadiene skeleton, an epoxy resin having a triglicidyl isocyanurate skeleton, an epoxy resin having a cardo skeleton, and an epoxy resin having a polysiloxane structure.

(Meth)acrylate having two or more functional groups can be used as the acryl resin. A water-dispersed acryl resin can be used as the acryl resin. The water-dispersed acryl resin is an acryl monomer, oligomer, or polymer dispersed in a dispersion medium containing water as a main component, and is a type of acryl resin which is hardly crosslinked in a dilute state such as an aqueous dispersion, but which is crosslinked and solidified even at a normal temperature when water is vaporized or a type of acryl resin which has a self-crosslinkable functional group and which is crosslinked and solidified only by heating without using an additive such as a catalyst, a polymerization initiator, or a reaction accelerater.

When the matrix layer 14 is composed of an inorganic material, for example, SiOx (0<x<2), SiNx (0<x<¾), GaN, Ga₂O₃, ZnO, and InGaN mixed crystal can be used.

The quantum dot 16 is formed of a wavelength conversion composition wavelength-converting light of a specific wavelength range of absorbed light into light having energy lower than that of the absorbed light. The quantum dots 16 perform the wavelength conversion function of the wavelength conversion film 12 (wavelength conversion element 10). For example, the quantum dots 16 are arranged so that the interval between the neighboring quantum dots 16 is equal to or less than the particle diameter of the quantum dots. 16 in the in-plane orientation of the matrix layer 14 or in at least one of the in-plane direction and the stacked direction when plural matrix layers 14 are stacked.

The quantum dots 16 are particulates and the particle diameter thereof ranges from 3 nm to 20 nm, preferably from 2 nm to 15 nm, and more preferably from 2 nm to 5 nm.

The bandgap of the quantum dots 16 is larger than the bandgap of the photoelectric conversion layer of the photoelectric conversion device on which the wavelength conversion element 10 is disposed. The quantum dots 16 are formed of, for example, Si, Ge, SiGe mixed crystal, InN, or InGaN mixed crystal.

For example, the quantum dots 16 have the function of wavelength-converting light in the wavelength range having energy of two or more times Eg of the photoelectric conversion layer on which the wavelength conversion element 10 is disposed into light having Eg of the photoelectric conversion layer. Accordingly, a material which absorbs energy of two or more times Eg of the photoelectric conversion layer and which has an energy level for absorbing light existing at the position of two or more times the photoelectric conversion bandgap is selected as the material of the quantum dots 16.

A material which emits light with energy higher than Eg of the photoelectric conversion layer is selected for the quantum dots 16. In this case, the material has a portion in which energy levels are discrete as well as or more than Eg of the photoelectric conversion layer, and a portion in which the energy transition probability between the energy levels is high is larger as compared to Eg of the photoelectric conversion layer.

In order to convert light into light usable in the photoelectric conversion layer, the quantum dots 16 need to be arranged so as to form a population inversion state in which the existence probability of photons in an excited state is higher than that in the ground state. Therefore, the quantum dots 16 are regularly arranged in a periodic arrangement of ABAB. Here, A represents a quantum dot and B represents a matrix layer. In this case, the periodic interval of the quantum dots 16 is equal to or less than 10 nm and preferably ranges from 2 nm to 5 nm, thereby obtaining the arrangement of the quantum dots 16 in which energy transfer of the excited photons can be attained. In order to cause localization of energy, a specific periodic interval of the quantum dots 16 has a variation in particle diameter of the quantum dots 16.

When the wavelength conversion element 10 has a multi-layered structure, in order to convert light into light usable in the photoelectric conversion layer, localization of energy is generated by causing the arrangements in the vertical direction and the horizontal direction of the quantum dots 16 to be different from each other. In this case, the quantum dots 16 have an arrangement different from the above-mentioned periodic arrangement of ABAB and have a deviation in particle density in a three-dimensional quantum-size space with sides of 20 nm or less, and thus the existence probability of photons can be changed.

Here, the vertical direction is the stacked direction, and the horizontal direction is a direction parallel to the plane of the matrix layer perpendicular to the stacked direction.

The particle diameter deviation σ_{d} of the quantum dots 16 varies in a range of 1<σ_{d}<10 nm and preferably in a range of 1<σ_{d}<5 nm.

Moreover, when the wavelength conversion element 10 has a multi-layered structure and when the arrangement of the quantum dots 16 in the stacked direction and the arrangement thereof in the direction perpendicular to the stacked direction are equal to each other, that is, when the quantum dots 16 are three-dimensionally and uniformly arranged at equal intervals like the above-mentioned periodic arrangement of ABAB in the wavelength conversion element 10, in order to convert light into light usable in the photoelectric conversion layer, localization of energy may be generated by the deviation in particle diameter of the quantum dots 16 to change the existence probability of photons. In this case as well, the particle diameter of the quantum dots 16 has a variation and the particle diameter deviation σ_{d} of the quantum dots 16 is in a range of 1<σ_{d}<10 nm and preferably in a range of 1<σ_{d}<5 nm, and the quantum dots 16 are made to vary in the above-mentioned range of deviation.

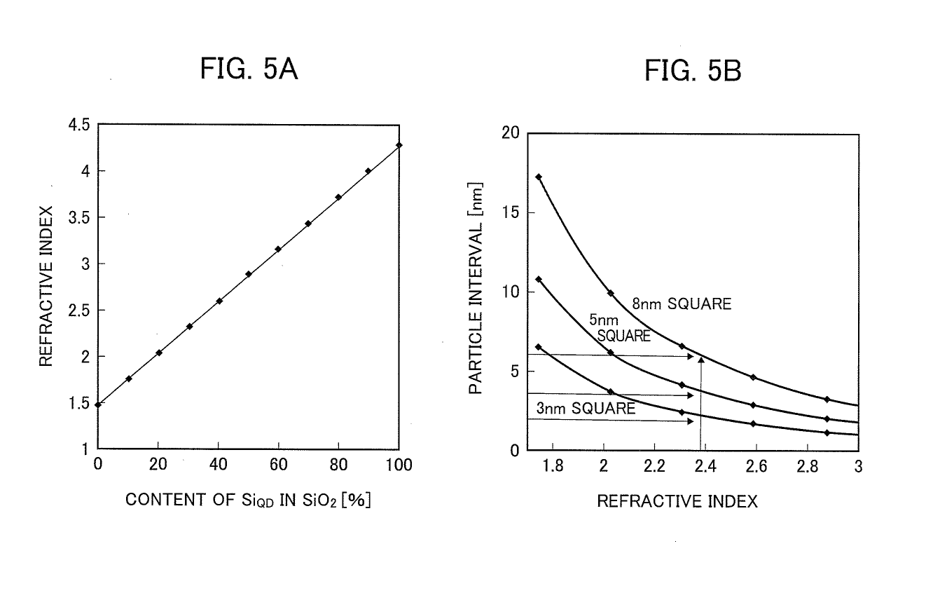

As described above, in order to obtain the antireflection function, the effective refractive index n of the wavelength conversion element 10 needs to be set to, for example, 2.4 which is an intermediate value between the refractive index of the photoelectric conversion layer and the refractive index of air. Therefore, the refractive index of the wavelength conversion element 10 comprising the wavelength conversion film 12 in which the matrix layer 14 is formed of SiO₂ and the quantum dots 16 are formed of Si was examined through simulating computation. A result was, as shown in FIG. 5A, that the larger the content of the quantum dots 16 was, the higher the refractive index was.

Further, the relationship between the interval of the quantum dots 16 and the refractive index was examined through simulating computation. A result was, as shown in FIG. 5B, that it was necessary to decrease the interval of the quantum dots 16 to increase the refractive index.

As shown in FIGS. 5A and 5B, for example, in order to set the effective refractive index n of the wavelength conversion element 10 to 2.4, it is necessary to narrow the interval of the quantum dots 16 and to arrange the quantum dots 16 in the matrix layer 14 with a high density.

Next, reflectance of a structure in which the wavelength conversion element 10 is formed on a Si substrate and a SiO₂ film is formed on the wavelength conversion element 10 was measured. The wavelength conversion element 10 has a structure in which the quantum dots 16 of Si are formed in the matrix layer 14 of SiO₂ (Si_{QD}/SiO₂ₘₐₜ) and the particle diameter of the quantum dots 16 is uniform. At this time, the refractive index of the wavelength conversion element 10 is 1.80.

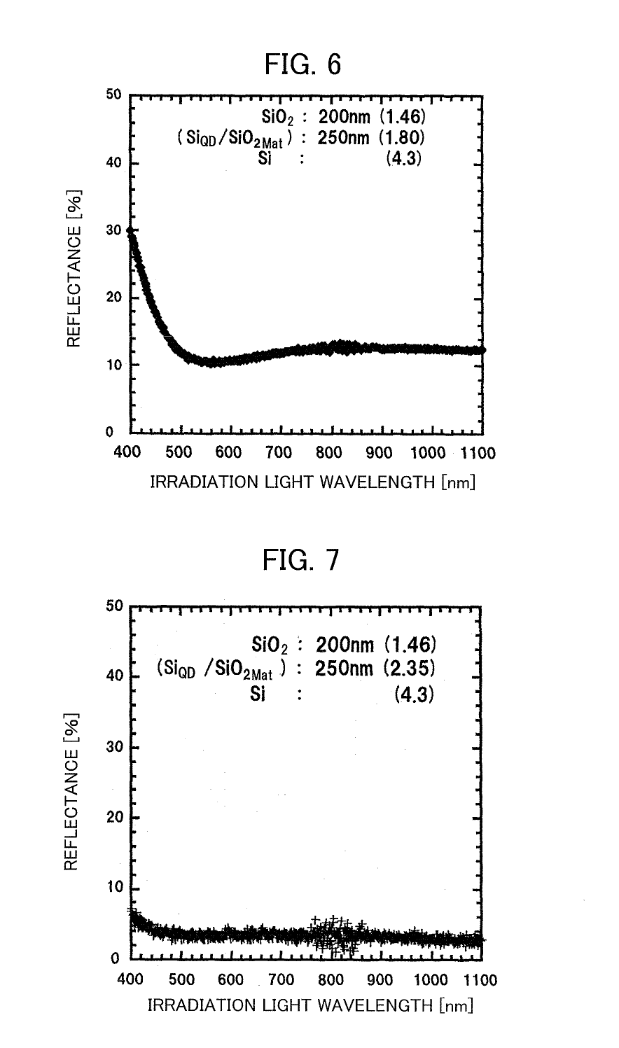

In this case, as shown in FIG. 6, the reflectance can be set to about 10%. The reflectance was measured using a spectral reflectometer (U4000 made by Hitachi Ltd.) by irradiating light while changing the wavelength of the irradiation light.

By setting the particle diameter of the quantum dots 16 to be non-uniform, the filling rate thereof was increased and the refractive index of the wavelength conversion element 10 was raised to 2.35. In this case, the wavelength conversion element 10 has a structure in which the quantum dots 16 of Si are formed in the matrix layer 14 of SiO₂ (Si_{QD}/SiO₂ₘₐₜ). The result is shown in FIG. 7. The reflectance was measured using a spectral reflectometer (U4000 made by Hitachi Ltd.) by irradiating light while changing the wavelength of the irradiation light.

As shown in FIG. 7, the reflectance can be further lowered from that in FIG. 6. Thus, by increasing the filling rate of the quantum dots 16, the refractive index can be raised and the reflectance can be decreased accordingly. The utilization efficiency of light L entering the wavelength conversion element 10 can be thus enhanced.

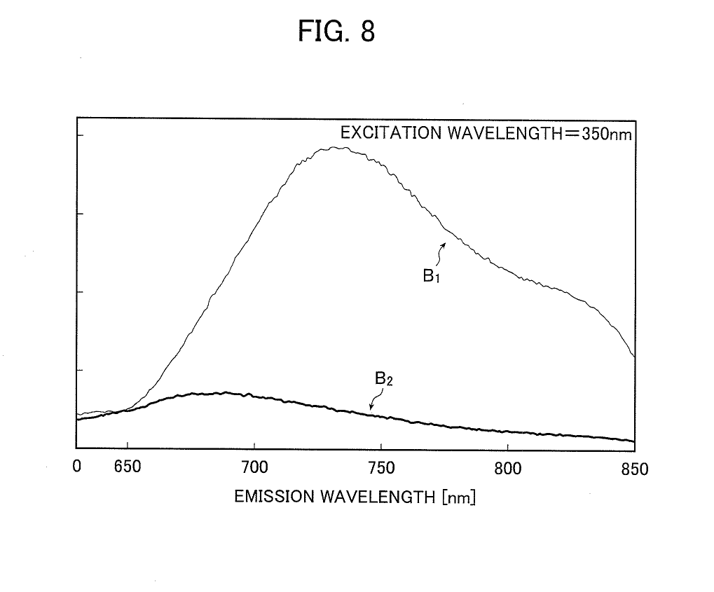

With the particle diameter of the quantum dots 16 kept uniform, the filling rate was increased and the effective refractive index of the wavelength conversion element 10 was raised to 2.4. The effective refractive index of the wavelength conversion element 10 with a uniform particle diameter is 1.80. The wavelength conversion element 10 with an effective refractive index of 2.4 and the wavelength conversion element 10 with an effective refractive index of 1.8 as mentioned above were irradiated with light of an excitation wavelength of 350 nm and the emission spectra shown in FIG. 8 were obtained. In FIG. 8, reference sign B₁ represents the wavelength conversion element 10 with an effective refractive index of 1.8 and reference sign B₂ represents the wavelength conversion element 10 with an effective refractive index of 2.4.

In the wavelength conversion element 10, as shown in FIG. 8, when the refractive index is simply raised while the particle diameter of the quantum dots 16 is kept uniform, the emission intensity thereof becomes smaller than that of one with a low refractive index. This is because: when the quantum dots 16 are densely arranged, e.g., when the interval of the quantum dots is very small to be equal to or less than 5 nm, energy transfer easily occurs between the quantum dots 16; and in addition, when the particle diameter of the quantum dots 16 is uniform, a deviation of energy hardly occur so that energy transfer is repeated without emitting light. Furthermore, since the matrix layer 14 is formed of an amorphous material having defects or the like and causes non-radiative recombination due to the defects of the matrix layer 14 or the like, the uniformity of quantum dots 16 causes a decrease in emission efficiency.

Therefore, a wavelength conversion element 10 in which the quantum dots 16 are formed of Ge, the matrix layer is formed of SiO₂, and the particle diameter of the quantum dots 16 is made uniform at about 5 nm was formed. In addition, a wavelength conversion element 10 in which the particle diameter of the quantum dots 16 is made non-uniform was formed.

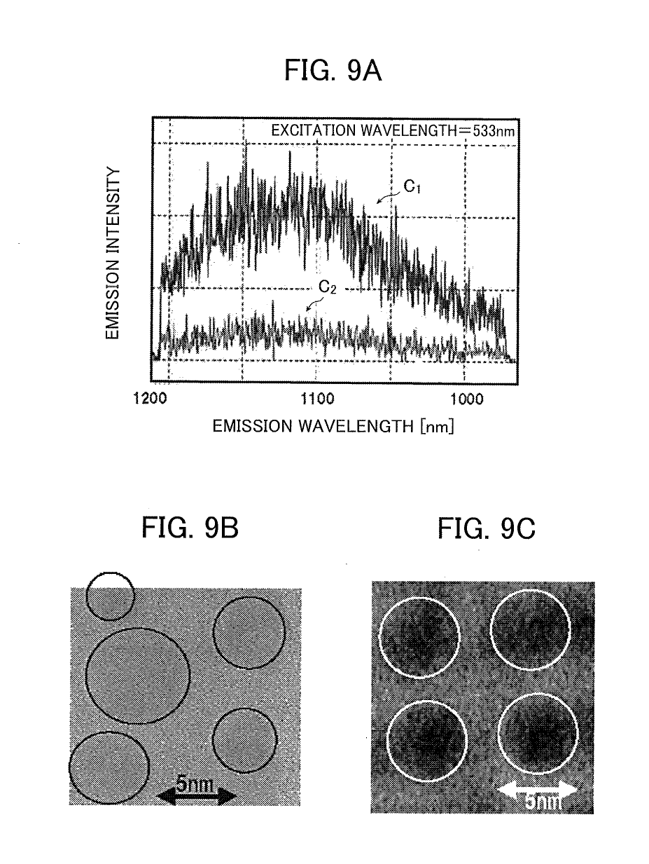

The wavelength conversion elements 10 were irradiated with light of an excitation wavelength of 533 nm and the emission spectra shown in FIG. 9A were obtained. In FIG. 9A, reference sign C₁ represents an emission spectrum of the wavelength conversion element comprising non-uniform quantum dots and reference sign C₂ represents an emission spectrum of the wavelength conversion element comprising uniform quantum dots. FIG. 9B is a diagram illustrating a TEM image of the wavelength conversion element comprising non-uniform quantum dots and FIG. 9C is a diagram illustrating a TEM image of the wavelength conversion element comprising uniform quantum dots.

As shown in FIG. 9A, the emission intensity obtained from the wavelength conversion element in which the particle diameter of the quantum dots is non-uniform is higher than that obtained from the wavelength conversion element in which the particle diameter of the quantum dots is uniform. Thus, as shown in FIGS. 8 and 9A, high emission intensity is obtained from the wavelength conversion element in which the particle diameter of the quantum dots is non-uniform.

In the wavelength conversion element 10 according to this embodiment, both the wavelength conversion function and the optical confinement function can be realized through the compositions of the matrix layer 14 and the quantum dots 16 and the arrangement of the quantum dots 16. Accordingly, when the wavelength conversion element is used for a photoelectric conversion device as described later, light not used for photoelectric conversion in the conventional technologies can be converted into light usable for the photoelectric conversion to enhance utilization efficiency of incident light such as sunlight light and the reflection of light which is not wavelength-converted can be suppressed, thereby improving conversion efficiency in the photoelectric conversion layer. In addition, it is possible to enhance emission intensity of wavelength-converted light by appropriately selecting the arrangement and the composition of the quantum dots 16.

Next, a method of manufacturing the wavelength conversion element 10 according to this embodiment will be described below.

The method of forming the wavelength conversion element 10 will be described with reference to an example where a Si substrate is used as a substrate (not shown), and the wavelength conversion element 10 comprising a matrix layer 14 formed of SiO₂ and the quantum dots 16 formed of Si is formed on the Si substrate.

First, for example, a Si substrate is prepared as a substrate (not shown).

Then, SiO₂ films to be the matrix layers 14 and Si films to be the quantum dots 16 are alternately stacked to form 61 layers with designed values of 5 nm, 5 nm, 5 nm, 3 nm, 5 nm, 5 nm, 5 nm, 3 nm, . . . , which is then subjected to heat treatment at 1000° C. for 2 hours in the atmosphere in which nitrogen gas continuously flows at a flow rate of 1 sccm, thereby performing crystallization. As a result, a wavelength conversion element 10 composed of the stacked 61 layers of wavelength conversion films 12 each of which is formed with the quantum dots 16 of Si in the matrix layer 14 of SiO₂ is formed.

In this case, regarding the film forming conditions of the SiO₂ film serving as the matrix layer 14, SiO₂ is used as a target, the input power is 100 W, the film forming pressure is 0.3 Pa, the gas flow rate of Ar gas is 15 sccm, and the gas flow rate of O₂ gas is 1 sccm.

Regarding the film forming conditions of the Si film serving as the quantum dots 16, Si is used as a target, the input power is 50 W, the film forming pressure is 0.3 Pa, the gas flow rate of Ar gas is 15 sccm, and the gas flow rate of O₂ gas is 0.35 sccm.

In the respective formation of the SiO₂ film and the Si film, the ultimate vacuum is equal to or less than 3×10⁻⁴ Pa and the substrate temperature is room temperature.

In this embodiment, in order to prevent generation of defects in the interface between the quantum dots 16 and the matrix layer 14 and in the matrix layer 14, it is preferable that a passivation step be provided. In the passivation step, a method of dipping the resultant in an ammonium sulfide solution or a cyanide solution or a method of heating the resultant in the atmosphere of hydrogen gas, hydrogen fluoride gas, hydrogen bromide gas, or hydrogen phosphide gas is used. Any of these methods is selected depending on the constituent material of the quantum dots 16. For example, a method of dipping the resultant in the cyanide solution and then washing the resultant with acetone, ethanol, and ultrapure water is used for Si-based quantum dots.

For example, the wavelength conversion element 10 according to this embodiment can be used for a solar cell as described later. Since the wavelength conversion element 10 can wavelength-convert, for example, light of a wavelength of 533 nm into light of a wavelength of 1100 nm, the wavelength conversion element 10 can be used as an infrared light source. In this case, by appropriately selecting the arrangement and the composition of the quantum dots 16, it is possible to enhance emission intensity of wavelength-converted light, that is, to enhance emission intensity of infrared rays.

In addition, by appropriately changing the bandgap of the quantum dots 16, for example, changing the bandgap to 3.5 eV, it is possible to wavelength-convert light into light having energy of 1.75 eV, that is, light of a wavelength of 800 nm. Hence, the wavelength conversion element 10 can be used as an ultraviolet protective film. Light having energy of 3.5 eV corresponds to light of a wavelength of 350 nm.

Next, a photoelectric conversion device using the wavelength conversion element 10 according to this embodiment will be described below.

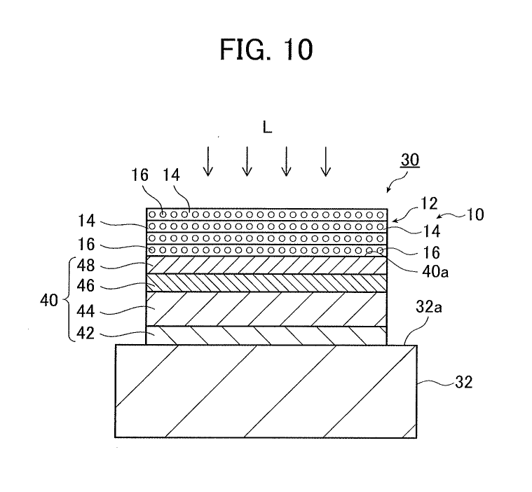

FIG. 10 is a schematic cross-sectional view illustrating a photoelectric conversion device having the wavelength conversion element according to the embodiment of the present invention.

In the photoelectric conversion device 30 shown in FIG. 10, a photoelectric conversion element 40 is disposed on a surface 32a of a substrate 32. The photoelectric conversion element 40 has an electrode layer 42, a P-type semiconductor layer (photoelectric conversion layer) 44, an N-type semiconductor layer 46, and a transparent electrode layer 48 staked in this order from the substrate 32 side.

The P-type semiconductor layer 44 is formed of, for example, polycrystalline silicon or monocrystalline silicon.

In this embodiment, the wavelength conversion element 10 is disposed on the surface 40a of the photoelectric conversion element 40 on the side of the transparent electrode layer 48. The P-type semiconductor layer 44 serves as a photoelectric conversion layer.

In this case, the wavelength conversion element 10 has a wavelength conversion function of wavelength-converting light in a wavelength range having energy of two or more times the bandgap 1.2 eV of Si constituting the P-type semiconductor layer 44 into light having energy of 1.2 eV which is half of the energy of the above-mentioned wavelength range and corresponds to the bandgap of Si, that is, light of a wavelength of 533 nm. Further, the effective refractive index of the wavelength conversion element 10 is set to an intermediate refractive index between the refractive index of Si and the refractive index of air.

Accordingly, since reflected light is decreased and light intensity of a wavelength usable for photoelectric conversion is increased by wavelength-converting light in a specific wavelength range not contributing to the photoelectric conversion into light usable for the photoelectric conversion, it is possible to improve conversion efficiency of the photoelectric conversion element 40 and to improve power generation efficiency of the entire photoelectric conversion device 30.

Here, when polycrystalline silicon is used for the P-type semiconductor layer 44 of the photoelectric conversion element 40, various plane orientations appear and thus the reflectance is not uniform. Consequently, even if an antireflection film effective for a certain plane orientation is formed, it is not effective for the entire photoelectric conversion layer. However, the wavelength conversion element 10 can prevent reflection of light in a wavelength range other than a specific wavelength range, thereby suppressing reflection loss to a low level. This point also contributes to improving power generation efficiency of the entire photoelectric conversion device 30.

When the wavelength conversion element 10 is provided, the wavelength conversion element 10 has only to be simply disposed on the surface 40a of the photoelectric conversion element 40 and etching or the like is not necessary. Accordingly, damage due to etching or the like does not occur in the photoelectric conversion device. As a result, it is possible to suppress occurrence of manufacturing failure.

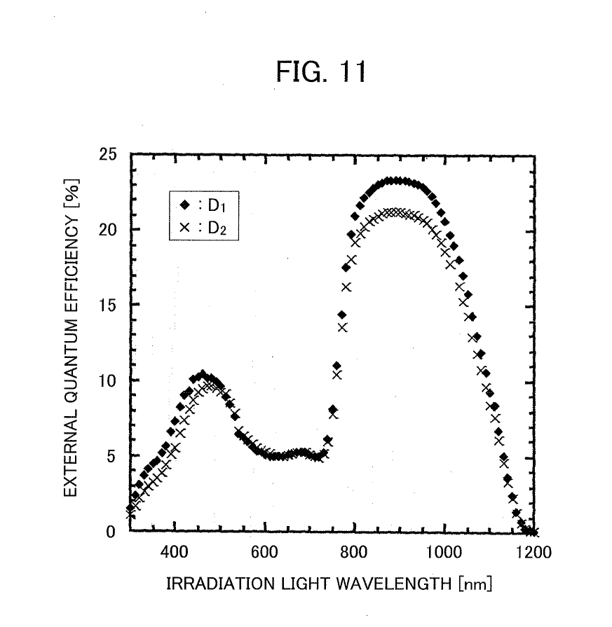

In the photoelectric conversion device 30, a difference in external quantum efficiency depending on a difference in refractive index of the wavelength conversion element 10 was examined with use of polycrystalline silicon as the P-type semiconductor layer 44 and by changing wavelength of irradiation light. The wavelength conversion elements 10 having the refractive index of 1.65 and that of 2.35 were used. As a result, as shown in FIG. 11, the external quantum efficiency was more improved with the wavelength conversion element 10 having the refractive index of 2.35 (reference sign D₁) than with the wavelength conversion element having the refractive index of 1.65 (reference sign D₂).

In the present invention, the photoelectric conversion layer is not limited to a photoelectric conversion layer in which silicon is used, and a CIGS-based photoelectric conversion layer, a CIS-based photoelectric conversion layer, a CdTe-based photoelectric conversion layer, a dye-sensitized photoelectric conversion layer, or an organic photoelectric conversion layer may also be used.

The present invention basically has the above-mentioned configuration. While the wavelength conversion element and the photoelectric conversion device according to the present invention are described in detail, the present invention is not limited to the above-mentioned embodiment but may be modified or changed in various forms without departing from the gist of the present invention.

What is claimed is:

1. A wavelength conversion element comprising:
at least one wavelength conversion layer comprising a matrix layer that is formed of a curable resin material or an inorganic material with a bandgap of 3 eV or more and particles that are disposed in the matrix layer, that are formed of a wavelength conversion composition for wavelength-converting absorbed light in a specific wavelength range into light having energy lower than energy of the absorbed light, and that have a particle diameter of 3 nm to 20 nm,
wherein the particles are arranged so that an interval between neighboring particles is equal to or less than the particle diameter of the particles, and
wherein the wavelength conversion layer prevents reflection of light in a wavelength range other than the specific wavelength range.

2. The wavelength conversion element according to claim 1, wherein a plurality of the wavelength conversion layers are stacked, and
wherein the particles of each matrix layer in a stacked direction are arranged so that an interval between neighboring particles in the stacked direction is equal to or less than the particle diameter of the particles.

3. The wavelength conversion element according to claim 1, wherein the interval between neighboring particles is equal to or less than 10 nm, a deviation σ_{d} of the particle diameter is 1<σ_{d}<10 nm, and the particle diameter of the particles varies in the range of the deviation.

4. The wavelength conversion element according to claim 1, wherein the particles are formed of Si, Ge, SiGe mixed crystal, InN, or InGaN mixed crystal.

5. The wavelength conversion element according to claim 1, wherein the inorganic material is SiOx (0<x<2), SiNx(0<x<¾), or InGaN mixed crystal.

6. A photoelectric conversion device comprising:
a photoelectric conversion layer; and
the wavelength conversion element according to claim 1 being disposed on an incident light side of the photoelectric conversion layer,
wherein the wavelength conversion element wavelength-converts light in a specific wavelength range with energy of two or more times a bandgap of the photoelectric conversion layer into light with energy of the bandgap of the photoelectric conversion layer and prevents reflection of light in a wavelength range other than the specific wavelength range.

7. The photoelectric conversion device according to claim 6, wherein an effective refractive index of the wavelength conversion element is an intermediate refractive index between a reflective index of the photoelectric conversion layer and a refractive index of air.

8. The photoelectric conversion device according to claim 7, wherein an effective refractive index n of the wavelength conversion element at a wavelength of 533 nm is 1.7<n<3.0.

9. The photoelectric conversion device according to claim 6, wherein a bandgap of the particles disposed in the matrix layer of the wavelength conversion element is larger than the bandgap of the photoelectric conversion layer.
